(19) United States
(12) Patent Application Publication
(10) Pub. No.: US 2025/0156742 A1
(43) Pub. Date: May 15, 2025

(54) APPLYING QUANTUM GATES INSIDE WIRE CUTS

(71) Applicant: INTERNATIONAL BUSINESS MACHINES CORPORATION, ARMONK, NY (US)

(72) Inventors: Stefan Woerner, Rueschlikon (CH); David Sutter, Zurich (CH)

(21) Appl. No.: 18/510,611

(22) Filed: Nov. 15, 2023

(51) Int. Cl. G06N 10/40; H03K 17/92

(52) U.S. Cl. CPC G06N 10/40; H03K 17/92

(57) ABSTRACT

A computer-implemented method for quantum circuit knitting can divide a quantum circuit into two or more sub-circuits. The method includes receiving, on a classical computer, a quantum circuit, and separating, also on the classical computer, the quantum circuit into a first quantum circuit and a second quantum circuit. The separation occurs along a quantum gate and the first quantum circuit and second quantum circuit do not include the quantum gate. On a quantum computer, the first quantum circuit can be performed and a result can be obtained. On the classical computer, the quantum gate can be applied to the result, creating a modified result and, on a quantum computer, the second quantum circuit can be performed using the modified result. The method can reduce the sampling cost for cutting the quantum circuit as compared to conventional quantum circuit cutting techniques.

### BACKGROUND

The present disclosure generally relates to systems and methods for cutting a gate or wire within a quantum circuit, and more particularly, to a computer-implemented method, a computer system, and a computer program product for applying gates inside a set of cut wires to achieve the smallest possible sampling overhead for cutting a gate or wire to simply a quantum circuit.

Hereinafter, a “Q” prefix in a word of phrase is indicative of a reference of that word or phrase in a quantum computing context unless expressly distinguished where used.

Molecules and subatomic particles follow the laws of quantum mechanics, a branch of physics that explores how the physical world works at the most fundamental levels. At this level, particles behave in strange ways, taking on more than one state at the same time, and interacting with other particles that are very far away. Quantum computing harnesses these quantum phenomena to process information.

The computers used today are known as classical computers (also referred to herein as “conventional” computers or conventional nodes, or “CN”). A conventional computer uses a conventional processor fabricated using semiconductor materials and technology, a semiconductor memory, and a magnetic or solid-state storage device, in what is known as a Von Neumann architecture. Particularly, the processors in conventional computers are binary processors, i.e., operating on binary data represented in 1 and 0.

A quantum processor (q-processor) uses the odd nature of entangled qubit devices (compactly referred to herein as “qubit,” plural “qubits”) to perform computational tasks. In the particular realms where quantum mechanics operates, particles of matter can exist in multiple states-such as an “on” state, an “off” state, and both “on” and “off” states simultaneously. Where binary computing using semiconductor processors is limited to using just the on and off states (equivalent to 1 and 0 in binary code), a quantum processor harnesses these quantum states of matter to output signals that are usable in data computing.

Conventional computers encode information in bits. Each bit can take the value of 1 or 0. These 1s and 0s act as on/off switches that ultimately drive computer functions. Quantum computers, on the other hand, are based on qubits, which operate according to two key principles of quantum physics: superposition and entanglement. Superposition means that each qubit can represent both a 1 and a 0 at the same time. Entanglement means that qubits in a superposition can be correlated with each other in a non-classical way; that is, the state of one (whether it is a 1 or a 0 or both) can depend on the state of another, and that there is more information that can be ascertained about the two qubits when they are entangled than when they are treated individually.

Using these two principles, qubits operate as more sophisticated processors of information, enabling quantum computers to function in ways that allow them to solve difficult problems that are intractable using conventional computers. IBM has successfully constructed and demonstrated the operability of a quantum processor using superconducting qubits (IBM is a registered trademark of International Business Machines corporation in the United States and in other countries.)

In quantum computing, and specifically, the quantum circuit model of computation, a quantum logic gate (or simply quantum gate) is a basic quantum circuit operating on a small number of qubits. They are the building blocks of quantum circuits, like classical logic gates are for conventional computing circuits.

Circuit knitting describes a set of techniques to cut a gate or a wire within a quantum circuit which can allow for the simplification of circuits (e.g., running a large circuit on small devices). The cost for such cuts is a sampling overhead that scales exponentially in the number of cuts. Hence it is of great relevance to develop cutting algorithms that achieve the smallest possible overhead.

### SUMMARY

In one embodiment, a computer implemented method and a computer program product can be configured for quantum circuit knitting to divide a quantum circuit into two or more sub-circuits. The method can include receiving, on a classical computer, a quantum circuit, and separating, also on the classical computer, the quantum circuit into a first quantum circuit and a second quantum circuit. The separation occurs along a quantum gate and the first quantum circuit and second quantum circuit do not include the quantum gate. On a quantum computer, the first quantum circuit can be performed and a result can be obtained. On the classical computer, the quantum gate can be applied to the result, creating a modified result and, on a quantum computer, the second quantum circuit can be performed using the modified result.

In another embodiment, a computing device configured to build a quantum circuit includes a processor operating a qubit circuit compiler engine and a memory coupled to the processor. The memory stores instructions to cause the processor to perform acts including receiving, on a classical computer, a quantum circuit, and separating, also on the classical computer, the quantum circuit into a first quantum circuit and a second quantum circuit. The separation occurs along a quantum gate and the first quantum circuit and second quantum circuit do not include the quantum gate. On a quantum computer, the first quantum circuit can be performed and a result can be obtained. On the classical computer, the quantum gate can be applied to the result, creating a modified result and, on a quantum computer, the second quantum circuit can be performed using the modified result.

These and other features will become apparent from the following detailed description of illustrative embodiments thereof, which is to be read in connection with the accompanying drawings.

### BRIEF DESCRIPTION OF THE DRAWINGS

The drawings are of illustrative embodiments. They do not illustrate all embodiments. Other embodiments may be used in addition or instead. Details that may be apparent or unnecessary may be omitted to save space or for more effective illustration. Some embodiments may be practiced with additional components or steps and/or without all the components or steps that are illustrated. When the same numeral appears in different drawings, it refers to the same or like components or steps.

FIG. 1 is a functional block diagram illustration of an environment for quantum computing that can be used to implement a method of quantum circuit knitting to divide a quantum circuit into two or more sub-circuits, consistent with an illustrative embodiment.

FIG. 2A is a block diagram of a hybrid computing system according to an embodiment.

FIG. 2B is a block diagram of an architecture, and data transmission, of hybrid computing system of FIG. 2A, consistent with embodiments.

FIG. 3 is a diagram of a four qubit circuit with a proposed set of wire cuts to divide the circuit into two smaller quantum circuits.

FIG. 4 is an illustration of the decomposition of a qubit during a wire cut, consistent with an illustrative embodiment.

FIG. 5 is an illustration of cutting a multi-qubit circuit, consistent with an embodiment.

FIG. 6 is a graph showing a gamma factor for cutting various multi-qubit circuits through a rotation gate.

FIG. 7 is a block diagram showing a comparison of salient cuts and the resulting sampling cost for two conventional algorithms as compared to algorithms, consistent with an illustrative embodiment.

### DETAILED DESCRIPTION

In the following detailed description, numerous specific details are set forth by way of examples to provide a thorough understanding of the relevant teachings. However, it should be apparent that the present teachings may be practiced without such details. In other instances, well-known methods, procedures, components, and/or circuitry have been described at a relatively high-level, without detail, to avoid unnecessarily obscuring aspects of the present teachings.

### Definitions

Quantum circuit, as used herein, is a program with an ordered sequence of quantum gates. At the end of every quantum circuit, there is measurement operation that collapses the quantum state of the qubit classically. When a quantum circuit is run multiple times, an average of the measurement operation can be obtained as an expectation value of an operator or probability values of computational basis states.

Qubit routing, as used herein, refers to the task of modifying quantum circuits so that they satisfy the connectivity constraints of a target quantum processor. This involves inserting SWAP gates into the circuit so that the logical gates only ever occur between adjacent physical qubits.

Quantum logic gate (or simply quantum gate), as used herein, refers to a basic quantum circuit operating on qubits. A quantum gate is a unitary matrix operation performed on either a single or multiple qubits to change the state(s). Some commonly used single qubit gates are bit-flip gate, Hadamard gate, Pauli X/Y/Z gates, RX/RY/RZ rotation gates, identity gate, T gate, S gate and multi qubit gates include CNOT gate, SWAP gate, Controlled SWAP gate, Toffoli gate, and iToffoli gate.

Qubit (or quantum bits), as used herein, refers to a basic unit of quantum information using the classic binary bit physically realized with a two-state device. Qubits are quantum equivalent of classical bits. While classical bits only have either 0 or 1 values, a qubit can have a range of values, which can be, in general, represented as a quantum state

$$\vert φ 〉 = [ \begin{matrix}α \\ β\end{matrix} ] ,$$

where |α²| represents the probability of the qubit being measured to 0, and |β²| represents the probability of the qubit being measured to 1. A qubit has two special states |0 [symbol] with α=1, β=0 and |1 [symbol] with α=0, β=1. These states are called computational basis states.

CNOT, as used herein, refers to a controlled NOT gate, which is a type of quantum logic gate.

Shot, as used herein, refers to the number of repeated quantum executions of a quantum circuit. Usually, multiple shots are used to compute expectation values and probability values. Higher the number of shots, more accurate will be the output.

Gate Cutting, as used herein, refers to the cutting of a multi-qubit quantum gate via a quasi-probability decomposition (QPD) using only local gates (possibly involving classical communication, as described in greater detail herein).

Wire Cutting, as used herein, refers to the cutting of one or more wires in a quantum circuit by rewriting them as a QPD using, e.g., measurement and prepare channels, or state teleportation.

Gamma, as used herein, refers to a “cost”, in terms of sampling overhead, such as number of required shots, introduced by a QPD.

### Overview

The present disclosure generally relates to quantum circuits, e.g., quantum circuit design including algorithms for cutting wires and/or gates in a quantum circuit to create two or more smaller circuits that can be run with certain hardware constraints. Quantum computing uses quantum physics to encode and process information rather than binary digital techniques based on transistors. A quantum computing device employs quantum bits (sometimes referred to as qubits) that operate according to the laws of quantum physics and can exhibit phenomena such as superposition and entanglement. The superposition principle of quantum physics allows qubits to be in a state that partially represent both a value of “1” and a value of “0” at the same time. The entanglement principle of quantum physics allows qubits to be correlated with each other such that the combined states of the qubits cannot be factored into individual qubit states. For instance, a state of a first qubit can depend on a state of a second qubit. As such, a quantum circuit can employ qubits to encode and process information in a manner that can be significantly different from binary digital techniques based on transistors. However, the designing of quantum circuits often can be relatively difficult and/or time consuming.

Aspects of the present disclosure can extend the understanding of possible ways to cut circuits and to reduce the overall costs (e.g., sampling costs) of circuit cutting. As illustrated in greater detail below, this can significantly reduce the cost of separating a quantum circuit into two or more smaller quantum circuits. Thus, the techniques described herein can be used by a quantum circuit compiler to optimize circuits given limited hardware connectivity, size, and quality. Together with other cutting approaches, the techniques of the present disclosure can be introduced into a circuit knitting toolbox and later integrated in a quantum circuit compiler. The reduced sampling costs can allow the running of significantly larger circuits on near-term hardware and can help to bridge the gap between “classical intractability” and “quantum advantage”. Thus, improved cutting techniques will be important short-term to solve larger problems, but also longer term as part of a circuit compiler, and the present disclosure provides an important building block for achieving these goals.

Importantly, although the operational/functional descriptions described herein may be understandable by the human mind, they are not abstract ideas of the operations/functions divorced from computational implementation of those operations/functions. Rather, the operations/functions represent a specification for an appropriately configured computing device. As discussed in detail below, the operational/functional language is to be read in its proper technological context, i.e., as concrete specifications for physical implementations.

It should be appreciated that aspects of the teachings herein are beyond the capability of a human mind. It should also be appreciated that the various embodiments of the subject disclosure described herein can include information that is impossible to obtain manually by an entity, such as a human user. For example, the type, amount, and/or variety of information included in performing the process discussed herein can be more complex than information that could be reasonably be processed manually by a human user.

According to an aspect of the present disclosure, there is provided a computer-implemented method, a system adopted for performing the computer-implemented method, and computer program code for performing the computer-implemented method of quantum circuit knitting to divide a quantum circuit into two or more sub-circuits. The computer implemented method includes receiving, on a classical computer, a quantum circuit, and separating, also on the classical computer, the quantum circuit into a first quantum circuit and a second quantum circuit. The separation occurs along a quantum gate and the first quantum circuit and second quantum circuit do not include the quantum gate. On a quantum computer, the first quantum circuit can be performed and a result can be obtained. On the classical computer, the quantum gate can be applied to the result, creating a modified result and, on a quantum computer, the second quantum circuit can be performed using the modified result.

In embodiments, which can be combined with the preceding embodiment, the quantum gate is a 2-quibit gate.

In embodiments, which can be combined with any one or more of the preceding embodiments, the separation includes decomposing, on the classical computer, each of the first quantum circuit and the second quantum circuit into a weighted sum of measure and prepare channels.

In embodiments, which can be combined with any one or more of the preceding embodiments, the quantum gate is a Clifford gate.

In embodiments, which can be combined with any one or more of the preceding embodiments, the method further includes permuting the prepare channels according to an action of the Clifford gate on Pauli matrices.

In embodiments, which can be combined with any one or more of the preceding embodiments, the gate is a non-Clifford gate.

In embodiments, which can be combined with any one or more of the preceding embodiments, the gate is a multi-qubit quantum gate.

In embodiments, which can be combined with any one or more of the preceding embodiments, the method further includes allowing classical communication between the first quantum circuit and the second quantum circuit to reduce a sampling computational overhead.

### Example Computing Environment

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

Computing environment 100 contains an example of an environment for the execution of at least some of the computer code involved in performing the inventive methods, such as, for example, some embodiments include a qubit circuit design engine 240 that determines a qubit circuit. In some embodiments, the qubit circuit design engine 240 may include a circuit compiler engine 245 that determines optimal qubit wire cutting to minimize sampling costs. The qubit circuit design engine 240 and circuit compiler engine 245 may operate according to one or more of the methods disclosed in further detail below. In addition to the qubit circuit design engine 240, computing environment 100 includes, for example, computer 101, wide area network (WAN) 102, end user device (EUD) 103, remote server 104, public cloud 105, and private cloud 106. In this embodiment, computer 101 includes processor set 110 (including processing circuitry 120 and cache 121), communication fabric 111, volatile memory 112, persistent storage 113, as identified above), peripheral device set 114 (including user interface (UI) device set 123, storage 124, and Internet of Things (IoT) sensor set 125), and network module 115. Remote server 104 includes remote database 130. Public cloud 105 includes gateway 140, cloud orchestration module 141, host physical machine set 142, virtual machine set 143, and container set 144.

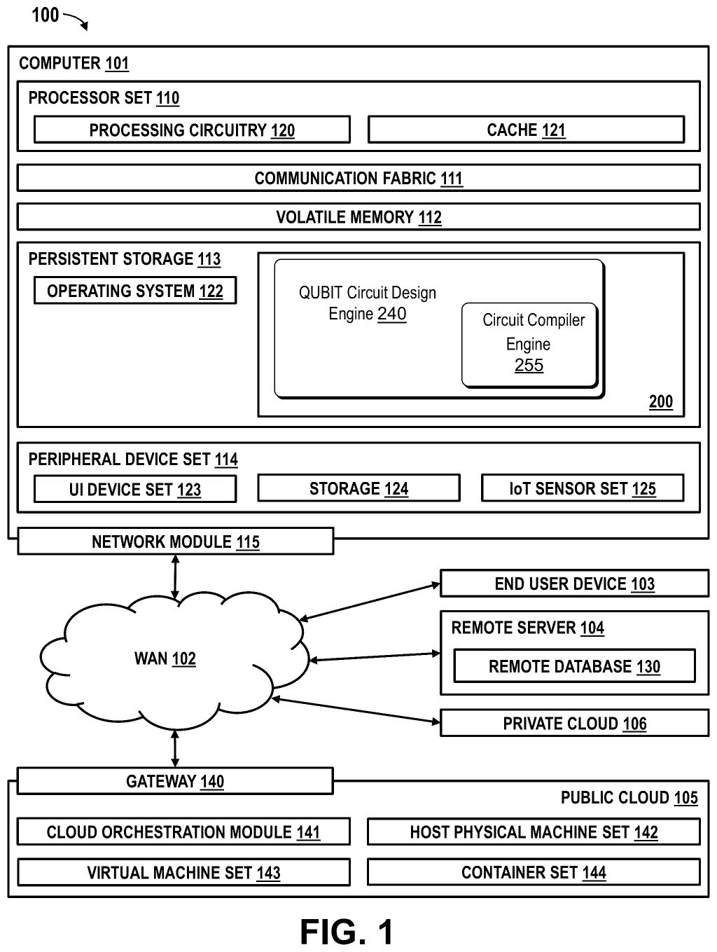

COMPUTER 101 may take the form of a desktop computer, laptop computer, tablet computer, smart phone, smart watch or other wearable computer, mainframe computer, or any other form of computer or mobile device now known or to be developed in the future that is capable of running a program, accessing a network or querying a database, such as remote database 130. As is well understood in the art of computer technology, and depending upon the technology, performance of a computer-implemented method may be distributed among multiple computers and/or between multiple locations. On the other hand, in this presentation of computing environment 100, detailed discussion is focused on a single computer, specifically computer 101, to keep the presentation as simple as possible. Computer 101 may be located in a cloud, even though it is not shown in a cloud in FIG. 1. On the other hand, computer 101 is not required to be in a cloud except to any extent as may be affirmatively indicated.

PROCESSOR SET 110 includes one, or more, computer processors of any type now known or to be developed in the future. Processing circuitry 120 may be distributed over multiple packages, for example, multiple, coordinated integrated circuit chips. Processing circuitry 120 may implement multiple processor threads and/or multiple processor cores. Cache 121 is memory that is located in the processor chip package(s) and is typically used for data or code that should be available for rapid access by the threads or cores running on processor set 110. Cache memories are typically organized into multiple levels depending upon relative proximity to the processing circuitry. Alternatively, some, or all, of the cache for the processor set may be located “off chip.” In some computing environments, processor set 110 may be designed for working with qubits.

Computer readable program instructions are typically loaded onto computer 101 to cause a series of operational steps to be performed by processor set 110 of computer 101 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 121 and the other storage media discussed below. The program instructions, and associated data, are accessed by processor set 110 to control and direct performance of the inventive methods. In computing environment 100, at least some of the instructions for performing the inventive methods may be stored in persistent storage 113.

COMMUNICATION FABRIC 111 is the signal conduction path that allows the various components of computer 101 to communicate with each other. Typically, this fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

VOLATILE MEMORY 112 is any type of volatile memory now known or to be developed in the future. Examples include dynamic type random access memory (RAM) or static type RAM. Typically, volatile memory 112 is characterized by random access, but this is not required unless affirmatively indicated. In computer 101, the volatile memory 112 is located in a single package and is internal to computer 101, but, alternatively or additionally, the volatile memory may be distributed over multiple packages and/or located externally with respect to computer 101.

PERSISTENT STORAGE 113 is any form of non-volatile storage for computers that is now known or to be developed in the future. The non-volatility of this storage means that the stored data is maintained regardless of whether power is being supplied to computer 101 and/or directly to persistent storage 113. Persistent storage 113 may be a read only memory (ROM), but typically at least a portion of the persistent storage allows writing of data, deletion of data and re-writing of data. Some familiar forms of persistent storage include magnetic disks and solid state storage devices. Operating system 122 may take several forms, such as various known proprietary operating systems or open source Portable Operating System Interface-type operating systems that employ a kernel. The code included in hybrid computing system 200 typically includes at least some of the computer code involved in performing the inventive methods.

PERIPHERAL DEVICE SET 114 includes the set of peripheral devices of computer 101. Data communication connections between the peripheral devices and the other components of computer 101 may be implemented in various ways, such as Bluetooth connections, Near-Field Communication (NFC) connections, connections made by cables (such as universal serial bus (USB) type cables), insertion-type connections (for example, secure digital (SD) card), connections made through local area communication networks and even connections made through wide area networks such as the internet. In various embodiments, UI device set 123 may include components such as a display screen, speaker, microphone, wearable devices (such as goggles and smart watches), keyboard, mouse, printer, touchpad, game controllers, and haptic devices. Storage 124 is external storage, such as an external hard drive, or insertable storage, such as an SD card. Storage 124 may be persistent and/or volatile. In embodiments where computer 101 is required to have a large amount of storage (for example, where computer 101 locally stores and manages a large database) then this storage may be provided by peripheral storage devices designed for storing very large amounts of data, such as a storage area network (SAN) that is shared by multiple, geographically distributed computers. IoT sensor set 125 is made up of sensors that can be used in Internet of Things applications. For example, one sensor may be a thermometer and another sensor may be a motion detector.

NETWORK MODULE 115 is the collection of computer software, hardware, and firmware that allows computer 101 to communicate with other computers through WAN 102. Network module 115 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 115 are performed on the same physical hardware device. In other embodiments (for example, embodiments that utilize software-defined networking (SDN)), the control functions and the forwarding functions of network module 115 are performed on physically separate devices, such that the control functions manage several different network hardware devices. Computer readable program instructions for performing the inventive methods can typically be downloaded to computer 101 from an external computer or external storage device through a network adapter card or network interface included in network module 115.

WAN 102 is any wide area network (for example, the internet) capable of communicating computer data over non-local distances by any technology for communicating computer data, now known or to be developed in the future. In some embodiments, the WAN 102 may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

END USER DEVICE (EUD) 103 is any computer system that is used and controlled by an end user (for example, a customer of an enterprise that operates computer 101), and may take any of the forms discussed above in connection with computer 101. EUD 103 typically receives helpful and useful data from the operations of computer 101. For example, in a hypothetical case where computer 101 is designed to provide a recommendation to an end user, this recommendation would typically be communicated from network module 115 of computer 101 through WAN 102 to EUD 103. In this way, EUD 103 can display, or otherwise present, the recommendation to an end user. In some embodiments, EUD 103 may be a client device, such as thin client, heavy client, mainframe computer, desktop computer and so on.

REMOTE SERVER 104 is any computer system that serves at least some data and/or functionality to computer 101. Remote server 104 may be controlled and used by the same entity that operates computer 101. Remote server 104 represents the machine(s) that collect and store helpful and useful data for use by other computers, such as computer 101. For example, in a hypothetical case where computer 101 is designed and programmed to provide a recommendation based on historical data, then this historical data may be provided to computer 101 from remote database 130 of remote server 104.

PUBLIC CLOUD 105 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 105 is performed by the computer hardware and/or software of cloud orchestration module 141. The computing resources provided by public cloud 105 are typically implemented by virtual computing environments that run on various computers making up the computers of host physical machine set 142, which is the universe of physical computers in and/or available to public cloud 105. The virtual computing environments (VCEs) typically take the form of virtual machines from virtual machine set 143 and/or containers from container set 144. It is understood that these VCEs may be stored as images and may be transferred among and between the various physical machine hosts, either as images or after instantiation of the VCE. Cloud orchestration module 141 manages the transfer and storage of images, deploys new instantiations of VCEs and manages active instantiations of VCE deployments. Gateway 140 is the collection of computer software, hardware, and firmware that allows public cloud 105 to communicate through WAN 102.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

PRIVATE CLOUD 106 is similar to public cloud 105, except that the computing resources are only available for use by a single enterprise. While private cloud 106 is depicted as being in communication with WAN 102, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 105 and private cloud 106 are both part of a larger hybrid cloud.

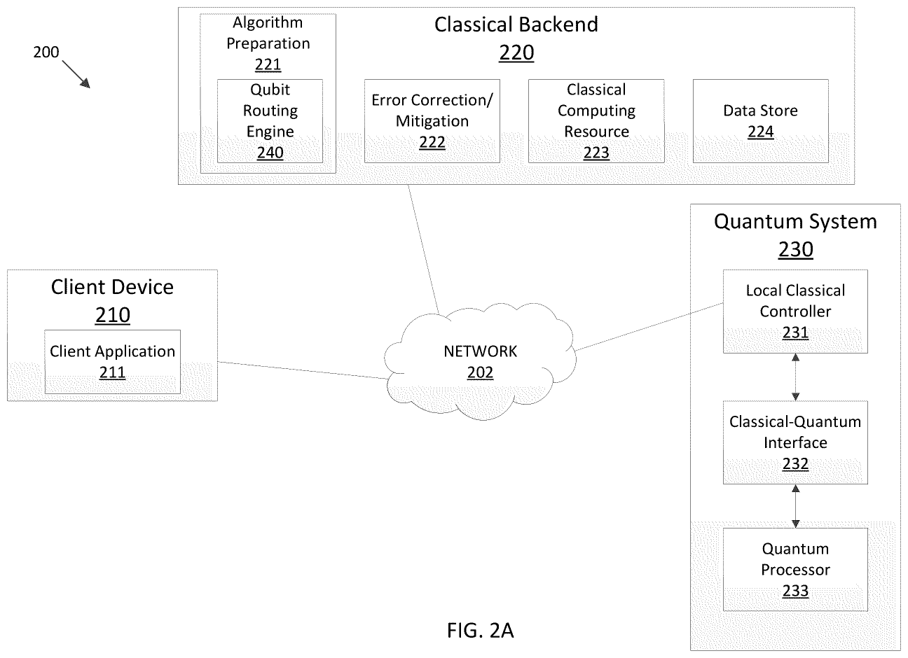

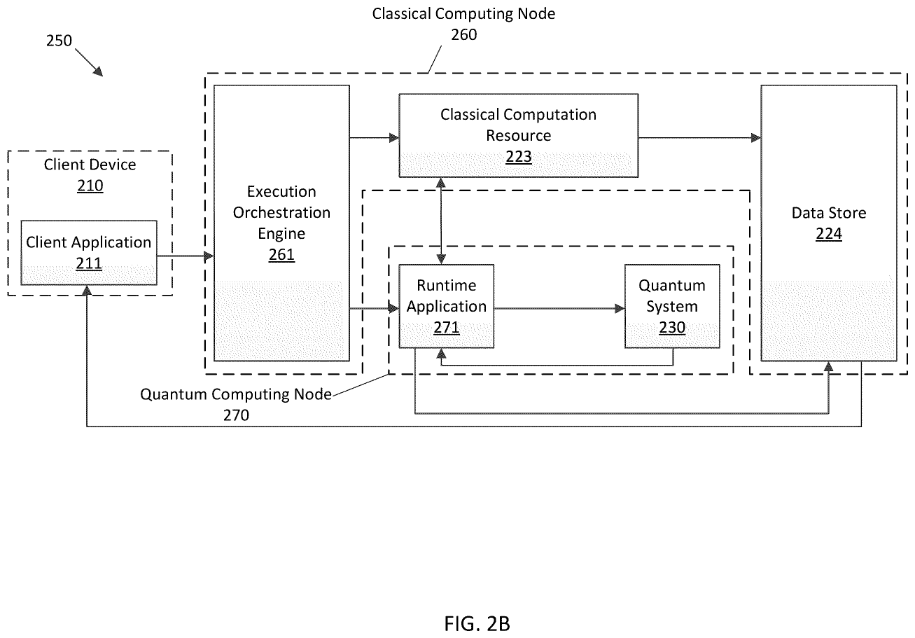

FIG. 2A illustrates a block diagram of an example hybrid computing system 200 that can facilitate execution of a quantum algorithm, such as an algorithm for optimizing wire and/or gate cutting of a qubit circuit. As shown, a client device 210 may interface with a classical backend 220 to enable computations with the aid of a quantum system 230.

Network 202 may be any combination of connections and protocols that will support communications between the client device 210, the classical backend 220, and the quantum system 230. In an example embodiment, network 202 may be substantially similar to WAN 102 of FIG. 1.

Client device 210 may be an implementation of computer 101 or EUD 103, described in more detail with reference to FIG. 1, configured to operate in a hybrid computing system 200.

Client application 211 may include an application or program code that includes computations requiring a quantum algorithm or quantum operation. In an embodiment, client application 211 may include an object-oriented programming language, such as Python® (“Python” is a registered trademark of the Python Software Foundation), capable of using programming libraries or modules containing quantum computing commands or algorithms, such as QISKIT (“QISKIT” is a registered trademark of the International Business Machines Corporation). In another embodiment, client application 211 may include machine level instructions for performing a quantum circuit, such as OpenQASM. Additionally, a user application may be any other high-level interface, such as a graphical user interface, having the underlying object oriented and/or machine level code as described above.

The classical backend 220 may be an implementation of computer 101, described in more detail with reference to FIG. 1, having program modules configured to operate in a hybrid computing system 200. Such program modules for classical backend 220 may include algorithm preparation 221, classical computation 223, and data store 224.

Algorithm preparation 221 may be a program or module capable of preparing algorithms contained in client application 211 for operation on quantum system 230. Algorithm preparation 221 may be instantiated as part of a larger algorithm, such as a function call of an API, or by parsing a hybrid classical-quantum computation into aspects for quantum and classical calculation. Algorithm preparation 221 may additionally compile or transpile quantum circuits that were included in client application 211 into an assembly language code for use by the local classical controller 231 to enable the quantum processor 233 to perform the logical operations of the circuit on physical structures. During transpilation/compilation an executable quantum circuit in the quantum assembly language may be created based on the calculations to be performed, the data to be analyzed, and the available quantum hardware.

In one example embodiment, algorithm preparation 221 may select a quantum circuit from a library of circuits that have been designed for use in a particular problem. In another example embodiment, algorithm preparation 221 may receive a quantum circuit from the client application 211 and may perform transformations on the quantum circuit to make the circuit more efficient, or to fit the quantum circuit to available architecture of the quantum processor 233. Additionally, algorithm preparation 221 may prepare classical data from data store 224, or client application 211, as part of the assembly language code for implementing the quantum circuit by the local classical controller 231. Algorithm preparation 221 may additionally set the number of shots (i.e., one complete execution of a quantum circuit) for each circuit to achieve a robust result of the operation of the algorithm.

Further, algorithm preparation 221 may update, or re-compile/re-transpile, the assembly language code based on parallel operations occurring in classical computing resource 223 or results received during execution of the quantum calculation on quantum system 230. Additionally, algorithm preparation 221 may determine the criterion for convergence of the quantum algorithm or hybrid algorithm. Algorithm Preparation 221 may include the qubit circuit design engine 240, using the associated qubit circuit compiler engine 245, which are explained in more detail below.

Error Suppression/Mitigation 222 may be a program or module capable of performing error suppression or mitigation techniques for improving the reliability of results of quantum computations. Error suppression is the most basic level of error handling. Error suppression refers to techniques where knowledge about the undesirable effects of quantum hardware is used to introduce customization that can anticipate and avoid the potential impacts of those effects, such as modifying signals from Classical-quantum interface 232 based on the undesirable effects. Error mitigation uses the outputs of ensembles of circuits to reduce or eliminate the effect of noise in estimating expectation values. Error mitigation may include techniques such as Zero Noise Extrapolation (ZNE) and Probabilistic Error Correction (PEC).

Classical computing resource 223 may be a program or module capable of performing classical (e.g., binary, digital) calculations contained in client application 211. Classical calculations may include formal logical decisions, artificial intelligence/machine learning (AI/ML) algorithms, floating point operations, and/or simulation of quantum operations.

Data store 224 may be a repository for data to be analyzed using a quantum computing algorithm, as well as the results of such analysis. Data store 224 may be an implementation of storage 124 and/or remote database 130, described in more detail with reference to FIG. 1, configured to operate in a hybrid computing system 200.

The quantum system 230 can be any suitable set of components capable of performing quantum operations on a physical system. In the example embodiment depicted in FIG. 2A, quantum system 230 includes a local classical controller 231, a classical-quantum interface 232, and quantum processor 233. In some embodiments, all or part of each of the local classical controller 231, a classical-quantum interface 232, and quantum processor 233 may be located in a cryogenic environment to aid in the performance of the quantum operations. In an embodiment, classical backend 220 and quantum system 230 may be co-located to reduce the communication latency between the devices.

Local classical controller 231 may be any combination of classical computing components capable of aiding a quantum computation, such as executing a one or more quantum operations to form a quantum circuit, by providing commands to a classical-quantum interface 232 as to the type and order of signals to provide to the quantum processor 233. Local classical controller 231 may additionally perform other low/no latency functions, such as error correction, to enable efficient quantum computations. Such digital computing devices may include processors and memory for storing and executing quantum commands using classical-quantum interface 232. Additionally, such digital computing devices may include devices having communication protocols for receiving such commands and sending results of the performed quantum computations to classical backend 220. Additionally, the digital computing devices may include communications interfaces with the classical-quantum interface 232. In an embodiment, local classical controller 231 may include all components of computer 101, or alternatively may be individual components configured for specific quantum computing functionality, such as processor set 110, communication fabric 111, volatile memory 112, persistent storage 113, and network module 115.

Classical-quantum interface 232 may be any combination of devices capable of receiving command signals from local classical controller 231 and converting those signals into a format for performing quantum operations on the quantum processor 233. Such signals may include electrical (e.g., RF, microwave, DC) or optical signals to perform one or more single qubit operations (e.g., Pauli gate, Hadamard gate, Phase gate, Identity gate), signals to preform multi-qubit operations (e.g., CNOT-gate, CZ-gate, SWAP gate, Toffoli gate), qubit state readout signals, and any other signals that might enable quantum calculations, quantum error correction, and initiate the readout of a state of a qubit. Additionally, classical-quantum interface 232 may be capable of converting signals received from the quantum processor 233 into digital signals capable of processing and transmitting by local classical controller 231 and classical backend 220. Such signals may include qubit state readouts. Devices included in classical-quantum interface 232 may include, but are not limited to, digital-to-analog converters, analog-to-digital converters, waveform generators, attenuators, amplifiers, filters, optical fibers, and lasers.

Quantum processor 233 may be any hardware capable of using quantum states to process information. Such hardware may include a collection of qubits, mechanisms to couple/entangle the qubits, and any required signal routings to communicate between qubits or with classical-quantum interface 232 in order to process information using the quantum states. Such qubits may include, but are not limited to, charge qubits, flux qubits, phase qubits, spin qubits, and trapped ion qubits. The architecture of quantum processor 233, such as the arrangement of data qubits, error correcting qubits, and the couplings amongst them, may be a consideration in performing a quantum circuit on quantum processor 233.

Referring now to FIG. 2B, a block diagram is depicted showing an example architecture, and data transmission, of hybrid computation system 250 employed using a cloud architecture for classical backend 220. Hybrid computation system 250 receives an algorithm including a computation from a client application 211 of client device 210. Upon receipt of the algorithm and request from client application 211, hybrid computation system 250 instantiates a classical computing node 260 and a quantum computing node 270 to manage the parallel computations. The classical computing node 260 may include one or more classical computers capable of working in tandem. For example, classical computing node 260 may include an execution orchestration engine 261, one or more classical computation resources 223, and a result data store 224. The network 202 may include a combination of classical and quantum computing components acting together to perform quantum calculations on quantum hardware including, for example, one or more quantum systems 230. The quantum computing node 270 may include a quantum runtime application 271 and one or more quantum systems 230.

The client application 211 may include programing instructions to perform quantum and classical calculations. In an embodiment, client application 211 may be in a general purpose computing language, such as an object oriented computing language (e.g., Python®), that may include classical and quantum functions and function calls. This may enable developers to operate in environments they are comfortable with, thereby enabling a lower barrier of adoption for quantum computation.

The execution orchestration engine 261, in using algorithm preparation 221, may parse the client application 211 into a quantum logic/operations portion for implementation on a quantum computing node 270, and a classical logic/operations portion for implementation on a classical computing node 260 using a classical computation resource 223. In an embodiment, parsing the client application 211 may include performing one or more data processing steps prior to operating the quantum logic using the processed data. In an embodiment, parsing the client application 211 may including segmenting a quantum circuit into portions that are capable of being processed by quantum computing node 270, in which the partial results of each of the segmented quantum circuits may be recombined as a result to the quantum circuit. Execution orchestration engine 261 may parse the hybrid algorithm such that a portion of the algorithm is performed using classical computation resources 223 and a session of quantum computing node 270 may open to perform a portion of the algorithm. Quantum runtime application 271 may communicate, directly or indirectly, with classical computation resources 223 by sending parameters/information between the session to perform parallel calculations and generate/update instructions of quantum assembly language to operate quantum system 230, and receiving parameters/information/results from the session on the quantum system 230.

Following the parsing of the hybrid algorithm for calculation on quantum computing node 270 and classical computing node 260, the parallel nodes may iterate the session to convergence by passing the results of quantum circuits, or partial quantum circuits, performed on quantum system 230 to classical computing resource 223 for further calculations. Additionally, quantum runtime application 271, using algorithm preparation 221, may re-parse aspects of the hybrid algorithm to improve convergence or accuracy of the result. Such operation results, and progress of convergence, may be sent back to client device 210 as the operations are being performed. By operating execution orchestration engine 261 in a cloud environment, the environment may scale (e.g., use additional computers to perform operations necessary) as required by the client application 211 without any input from the creators/implementors of client application 211. Additionally, execution orchestration engine 261, while parsing the client application 211 into classical and quantum operations, may generate parameters, function calls, or other mechanisms in which classical computation resource 223 and quantum computing node 270 may pass information (e.g., data, commands) between the components such that the performance of the computations enabled by client application 211 is efficient.

Classical computation resources 223 may perform classical computations (e.g., formal logical decisions, AI/ML algorithms, floating point operations, simulation of Quantum operations) that aid/enable/parallelize the computations instructed by client application 211. By utilizing classical computation resources 223 in an adaptively scalable environment, such as a cloud environment, the environment may scale (e.g., use additional computers to perform operations necessary including adding more classical computation resources 223, additional quantum systems 230, and/or additional resources of quantum systems 230 within a given quantum computing node 270) as required by the client application 211 without any input from the creators/implementors/developers of client application 211, and may appear seamless to any individual implementing client application 211 as there are no required programming instructions in client application 211 needed to adapt to the classical computation resources 223. Thus, for example, such scaling of quantum computing resources and classical computing resources may be provided as needed without user intervention. Scaling may reduce the idle time, and thus reduce capacity and management of computers in classical computing node 260. Result data store 224 may store, and return to client device 210, states, configuration data, etc., as well as the results of the computations of the client application 211.

Implementation of the systems described herein may enable hybrid computing system 200, through the use of quantum system 230, to process information, or solve problems, in a manner not previously capable. The efficient parsing of the quantum or hybrid algorithm into classical and quantum segments for calculation may achieve efficient and accurate quantum calculations from the quantum system 230 for problems that are exponentially difficult to perform using classical backend 220. Additionally, the quantum assembly language created by classical backend 220 may enable quantum system 230 to use quantum states to perform calculations that are not classically efficient or accurate. Specifically, the calculations analyze the different gate swapping permutations possible at different stages of a qubit circuit topology by using doubly stochastic matrices in the calculations. The use of doubly stochastic matrices determines qubit routes with an improved efficiency; for example, by reducing the number of gates needed which reduces the overall circuit depth. In addition, by eliminating the number of gates used in the quantum circuit, the error rate for the quantum circuit becomes reduced. Such improvement may reduce the classical resources required to perform the calculation of the quantum or hybrid algorithm, by improving the capabilities of the quantum system 230.

Accordingly, one or more of the methodologies discussed herein may provide methods for developing cutting algorithms that achieve the smallest possible overhead. Aspects of the present disclosure propose a novel technique to apply gates “inside” a set of cut wires. In other words, a quantum circuit can be divided into two separate, smaller quantum circuits, such as a first quantum circuit and a second quantum circuit, when the circuits are separated along a gate and none of the smaller quantum circuits include the gate.

For example, for Clifford gates this is free, i.e., no additional overhead is introduced to the costs of cutting the quantum circuit. However, for non-Clifford gates the additional costs may depend on the distance to the next Clifford gate but still is significantly smaller than cutting a gate directly. This may have the technical effect of significantly reducing computing resources and sampling overhead involved for cutting wires and/or gates in a qubit circuit to produce smaller circuits.

As is known, the overhead (in terms of the number of shots required to be run) of gate/wire cutting scales exponentially with the number of cuts, i.e., O(cⁿ) for n gate/wire cuts where c>1 is a constant. Hence, every improvement of the constant c can lead to a significantly larger number of feasible cuts. A good understanding of possible cutting techniques is crucial for near-term quantum circuit compilers that can take cutting into account when transpiling a circuit to a given hardware with limited connectivity.

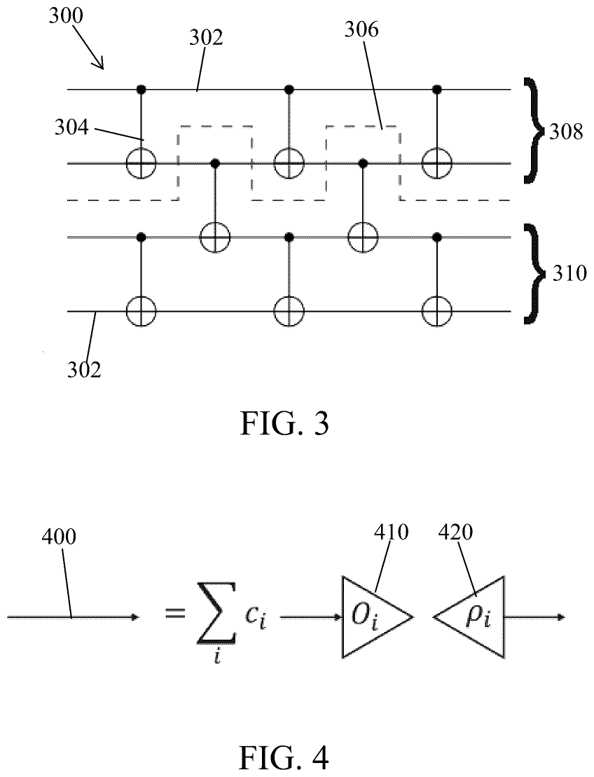

Referring to FIG. 3, an exemplary quantum circuit 300 is shown, with a plurality of qubits 302 moving therethrough. The circuit 300 can include a plurality of gates 304. While FIG. 3 shows a plurality of CNOT gates, it should be understood that various quantum gates may be used on the gates 304 in the circuit 300. Dashed line 306 illustrates a proposed cut to divide the circuit 300 into a first smaller circuit 308 and a second smaller circuit 310.

Each wire cut results in a sampling cost, where an increased number of shots are involved for operation of the first and second smaller circuits 308, 310 as compared to the operation of the overall quantum circuit 300.

FIG. 4 illustrates an exemplary wire 400 that can be cut and represented as a probabilistic mixture of local operations, where the identity of the wire 400 is decomposed into a weighted sum of measure channels 410 and prepare channels 420 including a measurement Oᵢ and a state ρᵢ. A conventional wire cut can result in the following measure and prepare channels:

$${O}_{1} = I , {ρ}_{1} = \vert 0 〉 〈 0 \vert , {c}_{1} = + 1 / 2 ,$$

$${O}_{2} = I , {ρ}_{2} = \vert 1 〉 〈 1 \vert , {c}_{2} = + 1 / 2 ,$$

$${O}_{3} = X , {ρ}_{3} = \vert + 〉 〈 + \vert , {c}_{3} = + 1 / 2 ,$$

$${O}_{4} = X , {ρ}_{4} = \vert - 〉 〈 - \vert , {c}_{4} = - 1 / 2 ,$$

$${O}_{5} = Y , {ρ}_{5} = \vert + i 〉 〈 + i \vert , {c}_{5} = + 1 / 2 ,$$

$${O}_{6} = Y , {ρ}_{6} = \vert - i 〉 〈 - i \vert , {c}_{6} = - 1 / 2 ,$$

$${O}_{7} = Z , {ρ}_{7} = \vert 0 〉 〈 0 \vert , {c}_{7} = + 1 / 2 ,$$

$${O}_{8} = Z , {ρ}_{5} = \vert 1 〉 〈 1 \vert , {c}_{8} = - 1 / 2 ,$$

The sampling overhead=(Gamma-factor)²=(Σᵢ|cᵢ|)², thus this optimal conventional method has a Gamma-factor of 4 per wire cut. If wire 400 is for qubit “a”, then cutting the wire at qubit “a” (wire 400) can be rewritten as

$$ρ = {\sum }_{i - 0}^{3} {tr}_{a} [ \frac{1}{\sqrt{2}} {σ}_{i} ρ ] ⊗ \frac{1}{\sqrt{2}} {σ}_{i}$$

where ρ represents the state of the physical object on the quantum circuit 300, σᵢ is a Pauli matrix that builds an orthogonal matrix, trₐ is a measurement from tracing out the qubit “a” and (1/√2)σ represents the preparation channel. Thus, the equation can be rewritten as

$$ρ = \frac{1}{2} {\sum }_{i - 0}^{3} {tr}_{a} [ {σ}_{i} ρ ] ⊗ {σ}_{i} .$$

Aspects of the present disclosure provide a cutting technique that can reduce the above described conventional sampling overhead. The cutting technique includes cutting a wire, followed by cutting a gate. Let U be a Clifford unitary acting on qubit a:

$$U ρ {U}^{†} = \frac{1}{2} {\sum }_{i - 0}^{3} {tr}_{a} [ {σ}_{i} ρ ] ⊗ U {σ}_{i} {U}^{†}$$

which, because Clifford gates map Pauli matrices to Pauli matrices, can be rewritten as

$$U ρ {U}^{†} = \frac{1}{2} {{\sum }_{i - 0}}^{3} {tr}_{a} [ {σ}_{i} ρ ] ⊗ {σ}_{u ( i )} .$$

Thus, to any cut, a Clifford gate can be applied by just permuting the state preparation channels according to the action of the Clifford gate on the Pauli matrices. This immediately extends to cuts of multiple qubits and multiqubit Clifford gates. Accordingly, a wire cut, followed by cutting a Clifford gate can result in the cutting of the applied Clifford gate without any additional sampling overhead.

While Clifford gates are a large class of unitary operations, it some embodiments, it may be desirable to apply a non-Clifford gate to the cut. In this example, let U by a non-Clifford unitary acting on qubit “a”, where σᵢ are Pauli matrices:

$$\begin{matrix}U ρ {U}^{†} = \frac{1}{2} {\sum }_{i = 0}^{3} {tr}_{a} [ {σ}_{i} ρ ] ⊗ U {σ}_{i} {U}^{†} \\ = \frac{1}{2} {\sum }_{i = 0}^{3} {tr}_{a} [ {σ}_{i} ρ ] ⊗ {\sum }_{j = 0}^{3} tr [ \frac{1}{\sqrt{2}} {σ}_{j} U {σ}_{i} {U}^{†} ] \frac{1}{\sqrt{2}} {σ}_{j} \\ = \frac{1}{4} {\sum }_{i , j = 0}^{3} tr [ {σ}_{j} U {σ}_{i} {U}^{†} ] {tr}_{a} [ {σ}_{i} ρ ] ⊗ {σ}_{j}\end{matrix} .$$

Replacing UσᵢU^{†} by a second QPD over the Pauli-basis allows the decomposition to get back into the measure and prepare setting. The additional traces only depend on the Pauli matrices and U and can be precomputed classically. Again, this can directly extend to cuts of multiple qubits and multi-qubit non-Clifford gates, as discussed in greater detail below. As can be seen by the above formula, the sampling overhead, while not zero for applying the cut to a non-Clifford gate, is less than the sampling overhead for adding a wire cut.

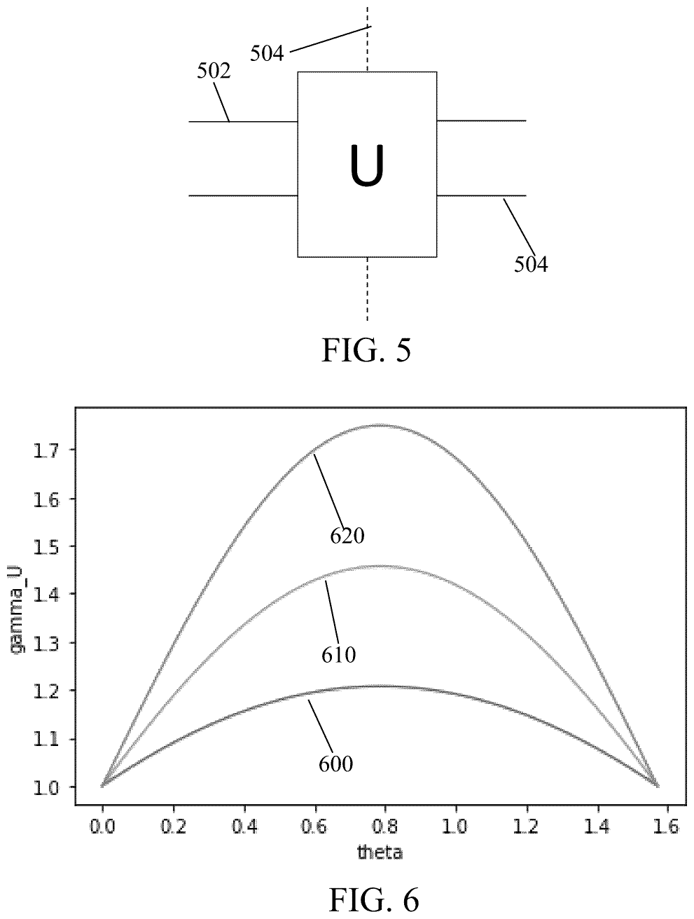

Referring now to FIG. 5, the gamma factor for making a cut 504 by cutting two wires 500, 502 and the gate U 510 can be determined. FIG. 6 shows the resulting gamma factors, depending on the angle, theta, for a rotation gate about an X-axis (line 600), for a rotation gate about two axes (line 610), and for a rotation gate about three axes (line 620). As can be seen in FIG. 6, for 2-qubits, the maximal overhead is achieved by 1.75 if a KAK decomposition of an arbitrary 2-qubit gate is used and the single qubit gates before/after the 2-qubit gates are moved to before/after the cut (otherwise the additional cost could exceed 1.75). Recall that the conventional gamma factor for a single wire cut is 4. As can be seen, the gamma factor (which equates to the sampling cost) is lower for applying the non-Clifford gate to the cut.

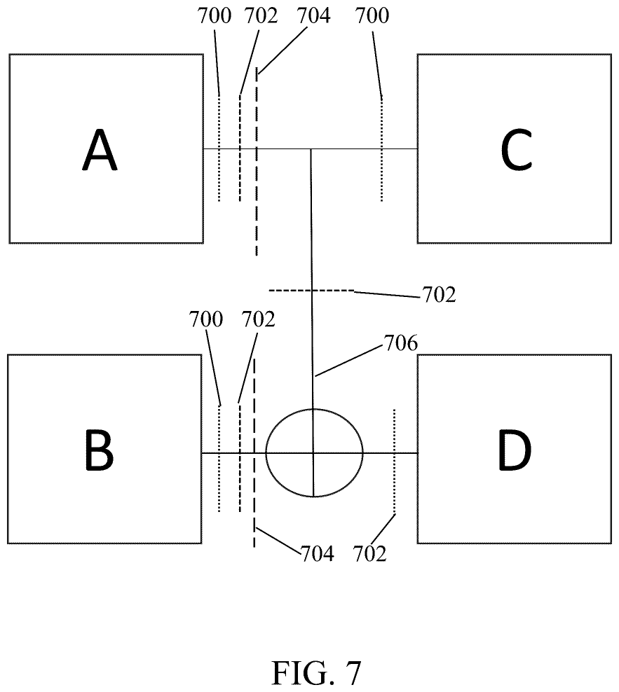

Referring to FIG. 7, there are shown three methods for cutting a circuit to form four separate sub-circuits, A, B, C, and D that can be executed individually, e.g., on a smaller device, such as a device with less computational ability and resources. Conventional processes would either cut wires and gate, or to cut wires before and after a gate. Depending on the situation, this can lead to significantly larger costs, as illustrated in the following example of FIG. 7.

A first conventional approach, indicated by dotted lines 700 cuts the wires before and after the CNOT gate. The gamma factor for these cuts is 4 per cut wire. Thus, the total gamma for this approach is 44=64. A second conventional approach, indicated by short-dashed lines 702 cuts the gate 706 (with a gamma factor=3), as well as two wires before or after the gate 706. This results in a total gamma factor of 3*(4²)=48.

According to aspects of the present disclosure, in this example, two wires can be cut (gamma factor is 4 for a cut wire) and the CNOT gate can be applied “inside the cut” (for “free”, without requiring any additional increase in the gamma factor, and thus, without any increase in the sampling cost). In other words, the CNOT gate can be applied to the circuit and cut at no additional sampling cost. The total gamma factor in this case is 4²=16. As can be seen, by utilizing methods of the present disclosure, the gamma factor for preparing smaller quantum circuits can be significantly reduced.

While the above description describes the circuit cutting within local operations, it should be understood that the Gamma-factor can also be reduced by allowing for classical communication (CC) between the cut subparts. This can reduce the sampling cost per cut from 4 to 3. The approaches of the present disclosure, by applying gates within the cut, still applies the same way, since the local operation with classical communication (LOCC) protocol still fits into the measure and prepare decomposition setting and the additional gate only modifies the prepare step.

### CONCLUSION

The descriptions of the various embodiments of the present teachings have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

While the foregoing has described what are considered to be the best state and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications, and variations that fall within the true scope of the present teachings.

The components, steps, features, objects, benefits, and advantages that have been discussed herein are merely illustrative. None of them, nor the discussions relating to them, are intended to limit the scope of protection. While various advantages have been discussed herein, it will be understood that not all embodiments necessarily include all advantages. Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

Numerous other embodiments are also contemplated. These include embodiments that have fewer, additional, and/or different components, steps, features, objects, benefits and advantages. These also include embodiments in which the components and/or steps are arranged and/or ordered differently.

Aspects of the present disclosure are described herein with reference to a flowchart illustration and/or block diagram of a method, apparatus (systems), and computer program products according to embodiments of the present disclosure. It will be understood that each block of the flowchart illustrations and/or block diagrams, and combinations of blocks in the flowchart illustrations and/or block diagrams, can be implemented by computer readable program instructions.

These computer readable program instructions may be provided to a processor of an appropriately configured computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The call-flow, flowchart, and block diagrams in the figures herein illustrate the architecture, functionality, and operation of possible implementations of systems, methods, and computer program products according to various embodiments of the present disclosure. In this regard, each block in the flowchart or block diagrams may represent a module, segment, or portion of instructions, which comprises one or more executable instructions for implementing the specified logical function(s). In some alternative implementations, the functions noted in the blocks may occur out of order noted in the Figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

While the foregoing has been described in conjunction with exemplary embodiments, it is understood that the term “exemplary” is merely meant as an example, rather than the best or optimal. Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity or action from another without necessarily requiring or implying any actual such relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a” or “an” does not, without further constraints, preclude the existence of additional identical elements in the process, method, article, or apparatus that comprises the element.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments have more features than are expressly recited in each claim. Rather, as the following claims reflect, the inventive subject matter lies in less than all features of a single disclosed embodiment. Thus, the following claims are hereby incorporated into the Detailed Description, with each claim standing on its own as a separately claimed subject matter.

What is claimed is:

1. A computer-implemented method for quantum circuit knitting to divide a quantum circuit into two or more sub-circuits, comprising:
receiving, on a classical computer, a quantum circuit;
separating, on the classical computer, the quantum circuit into a first quantum circuit and a second quantum circuit, wherein the separation occurs along a quantum gate, and wherein the first quantum circuit and second quantum circuit do not include the quantum gate;
performing, on a quantum computer, the first quantum circuit and measuring a result;
applying, on the classical computer, the quantum gate to the result creating a modified result; and
performing, on the quantum computer, the second quantum circuit using the modified result.

2. The computer-implemented method of claim 1, wherein the quantum gate is a 2-quibit gate.

3. The computer-implemented method of claim 1, wherein the separation includes decomposing, on the classical computer, each of the first quantum circuit and the second quantum circuit into a weighted sum of measure and prepare channels.

4. The computer-implemented method of claim 3, wherein the quantum gate is a Clifford gate.

5. The computer-implemented method of claim 4, further comprising permuting the prepare channels according to an action of the Clifford gate on Pauli matrices.

6. The computer-implemented method of claim 1, wherein the quantum gate is a non-Clifford gate.

7. The computer-implemented method of claim 1, wherein the quantum gate is a multi-qubit quantum gate.

8. The computer-implemented method of claim 1, further comprising allowing classical communication between the first quantum circuit and the second quantum circuit to reduce a sampling computational overhead.

9. A computing device configured to build a quantum circuit, comprising:
a processor operating a qubit circuit compiler engine; and
a memory coupled to the processor, the memory storing instructions to cause the processor to perform acts comprising:
receiving, on a classical computer, a quantum circuit;
separating, on the classical computer, the quantum circuit into a first quantum circuit and a second quantum circuit, wherein the separation occurs along a quantum gate, and wherein the first quantum circuit and second quantum circuit do not include the quantum gate;
performing, on a quantum computer, the first quantum circuit and measuring a result;
applying, on the classical computer, the quantum gate to the result creating a modified result; and
performing, on the quantum computer, the second quantum circuit using the modified result.

10. The computing device of claim 9, wherein quantum gate is a 2-quibit gate.

11. The computing device of claim 9, wherein the separation includes decomposing, on the classical computer, each of the first quantum circuit and the second quantum circuit into a weighted sum of measure and prepare channels.

12. The computing device of claim 11, wherein the quantum gate is a Clifford gate.

13. The computing device of claim 12, wherein the instructions are further configured to permute the prepare channels according to an action of the quantum gate on Pauli matrices.

14. The computing device of claim 9, wherein the quantum gate is a non-Clifford gate.

15. The computing device of claim 9, wherein the quantum gate is a multi-qubit quantum gate.

16. The computing device of claim 9, wherein the instructions are further configured to allow classical communication between the first quantum circuit and the second quantum circuit to reduce a sampling computational overhead.

17. A computer program product for quantum circuit knitting to divide a quantum circuit into two or more sub-circuits, the computer program product comprising a computer readable storage medium having program instructions embodied therewith, the program instructions executable by a computer to cause the computer to:
receiving, on a classical computer, a quantum circuit;
separating, on the classical computer, the quantum circuit into a first quantum circuit and a second quantum circuit, wherein the separation occurs along a quantum gate, and wherein the first quantum circuit and second quantum circuit do not include the quantum gate;
performing, on a quantum computer, the first quantum circuit and measuring a result;
applying, on the classical computer, the quantum gate to the result creating a modified result; and
performing, on the quantum computer, the second quantum circuit using the modified result.

18. The computer program product of claim 17, wherein the separation includes decomposing, on the classical computer, each of the first quantum circuit and the second quantum circuit into a weighted sum of measure and prepare channels.

19. The computer program product of claim 18, wherein:
the quantum gate is a Clifford gate; and
the prepare channels are permuted according to an action of the Clifford gate on Pauli matrices.

20. The computer program product of claim 17, wherein the instructions are further configured to allow classical communication between the first quantum circuit and the second quantum circuit to reduce a sampling computational overhead.
